(19) United States
(12) Patent Application Publication
(10) Pub. No.: US 2023/0058720 A1
(43) Pub. Date: Feb. 23, 2023

(54) INTEGRATED CIRCUIT INTERCONNECTION STRUCTURE

(71) Applicant: STMicroelectronics (Crolles 2) SAS, Crolles (FR)

(72) Inventors: Sylvie DEL MEDICO, Crolles (FR); Jean-Christophe GRENIER, Pontcharra (FR); Jean-Christophe GIRAUDIN, Saint-Nazaire-Les-Eymes (FR); Philippe KOWALCZYK, Grenoble (FR); Fausto PIAZZA, Grenoble (FR)

(73) Assignee: STMicroelectronics (Crolles 2) SAS, Crolles (FR)

(21) Appl. No.: 17/885,406

(22) Filed: Aug. 10, 2022

(30) Foreign Application Priority Data
Aug. 20, 2021 (FR) 2108802

(51) Int. Cl. H01L 23/00; H01L 21/027

(52) U.S. Cl. CPC H01L 24/13; H01L 21/0274; H01L 24/32; H01L 24/73; H01L 2224/13147; H01L 2224/32225; H01L 2224/73203

(57) ABSTRACT

The present description relates to a method of manufacturing an interconnection structure of an integrated circuit intended to be encapsulated in an encapsulation resin in contact with a first surface of a protection layer. The protection layer is resting on a first surface of the interconnection structure. The interconnection structure comprising copper interconnection elements extending at least partly through an insulating layer and flush with the first surface of said interconnection structure. The manufacturing method includes a step of structuring of the protection layer or a step of forming of the protection layer with a structuring. The structuring step or the forming step is adapted to structuring the first surface of the protection layer in the form of an alternation of ridges and troughs.

This application claims the priority benefit of French patent application number 2108802, filed on 20/08/2021, entitled “Structure d’interconnexion d’un circuit integre” which is hereby incorporated by reference to the maximum extent allowable by law.

### BACKGROUND

### Technical Field

The present disclosure generally relates to integrated circuits, and more particularly integrated circuit interconnection structures and methods of manufacturing these interconnection structures. The present disclosure particularly relates to integrated circuit interconnection structures intended to be encapsulated by means of a resin in an electronic package.

### Description of the Related Art

An integrated circuit comprises electronic components formed inside and/or on top of a semiconductor layer (or substrate). The integrated circuit further comprises an interconnection structure resting on the semiconductor layer. The interconnection structure comprises insulating layers having interconnection elements such as conductive vias, conductive tracks, and/or conductive pads arranged therein. The vias cross one or a plurality of insulating layers of the interconnection structure to electrically couple together conductive tracks and/or circuit components and/or conductive pads formed at the upper level (that is, the level most distant from the substrate) of the interconnection structure.

The vias, the conductive tracks, and in particular the conductive pads formed at the upper level of the interconnection structure may be made of copper, which more and more replaces aluminum in electronic circuits. Indeed, copper being a better conductor than aluminum, copper interconnection elements may have smaller dimensions than those made of aluminum, and use less energy to conduct electricity therethrough.

Copper (Cu) interconnects, and particularly vias or conductive pads, are generally formed by a so-called “damascene” method comprising:
a step of photolithography on an insulating layer to form on an upper surface of said layer a resin pattern capable of forming an etch mask;
a step of etching from the upper surface of the insulating layer covered with the resin pattern, to form trenches and/or holes in said insulating layer;
a step of deposition of a copper layer to fill with copper the trenches and/or the holes; and
a step of polishing (or “planarization”) of the upper surface of the interconnection structure so that the copper pads are flush with the upper surface of the insulating layer.

Due to this polishing step, the upper surface of the interconnection structure is a planar surface, which makes more difficult the encapsulation of such an integrated circuit with a resin to integrate it in an electronic package. For example, an unwanted phenomenon of delamination of the resin at the level of the contact with the interconnection structure may occur.

### BRIEF SUMMARY

There is a desire to overcome this encapsulation problem in resin of an integrated circuit comprising such an interconnection structure.

An embodiment overcomes all or part of the disadvantages of known interconnection structures.

An embodiment provides a method of manufacturing an interconnection structure of an integrated circuit intended to be encapsulated in an encapsulation resin in contact with a first surface of a protection layer, said protection layer resting on a first surface of the interconnection structure, the interconnection structure comprising copper interconnection elements extending at least partly through an insulating layer and flush with the first surface of said interconnection structure.

The manufacturing method comprises a step of structuring of the protection layer or a step of forming of the protection layer with a structuring, said structuring step or said forming step being adapted to structuring the first surface of the protection layer in the form of an alternation of ridges and troughs.

The second face of the protective layer, corresponding to the face opposite the first face of said protective layer, is for example in contact with the first face of the interconnection structure, and thus with the interconnection elements in copper that are flush with said first face of said interconnect structure.

In addition, it is specified that the structuring of the protective layer is a structuring formed from the first face of said protective layer, which does not cross said layer protection, and therefore does not form an opening in said protective layer.

According to an embodiment, the structuring step comprises:
a photolithography step adapted to forming a resin pattern on the first surface of the protection layer, said formed resin pattern being in the form of a succession of protrusions separated by openings; and then
a step of etching from the first surface of the protection layer, said etch step being adapted to etching at least a portion of said protection layer and being carried out via the resin pattern forming an etch mask, to form in said protection layer ridges separated by troughs. According to an example, the protrusions are substantially rectangular.

According to a specific embodiment, the widths of the troughs are in the range from 50 nm to 5 µm, preferably in the range from 50 to 200 nm, and/or the height of the troughs is in the range from 50 nm to 500 nm, preferably in the range from 100 to 200 nm.

According to an embodiment, the structuring step comprises a step of chemical-mechanical polishing of the first surface of the protection layer, said polishing step being adapted to forming a roughness greater than or equal to 5 nanometers, on the first surface of said protection layer, the roughness being defined by the root mean square height of the ridges of a surface with respect to an average level defined for said surface.

According to a specific embodiment, the polishing step implements a slurry polishing solution comprising abrasive balls.

According to an embodiment, the step of forming the protection layer with a structuring comprises:
a step of etching of a first surface of the insulating layer from the first surface of the interconnection structure, said etching step being carried out between interconnection elements, to form trenches between said interconnection elements in said insulating layer, so that at least a portion of said interconnection elements protrudes above the first surface of the etched insulating layer;
a step of forming of a protection layer in the trenches and on the protruding portion of the interconnection elements;
said etching and forming steps being adapted to structuring the first surface of the protection layer in the form of an alternation of ridges and troughs.

According to a specific embodiment, the widths of the trenches are greater than or equal to 2 µm and/or the height of the trenches is in the range from 20 to 300 nm, preferably from 150 to 250 nm.

According to a specific embodiment, the height of the trenches is in the range from 20 to 100 nm, preferably in the range from 25 to 75 nm.

According to an embodiment, the step of forming of the protection layer with a structuring comprises, prior to the step of etching of the insulating layer:
a photolithography step adapted to forming a resin pattern on the first surface of the interconnection structure, the formed resin pattern being in the form of a succession of protrusions separated by openings;
the step of etching of the insulating layer being carried out via the resin pattern forming an etch mask, the protrusions being positioned to mask at least the interconnection elements. According to an example, the protrusions are substantially rectangular.

According to an embodiment, the protection layer is formed by a chemical vapor deposition technique, for example, by plasma-enhanced chemical vapor deposition.

An embodiment provides an integrated circuit comprising an interconnection structure resting on a semiconductor layer, said integrated circuit being intended to be encapsulated in an encapsulation resin in contact with a first surface of a protection layer, said protection layer resting on a first surface of the interconnection structure, the interconnection structure comprising interconnection elements at least partly extending through an insulating layer and flush with the first surface of said interconnection structure, the first surface of the protection layer being structured in the form of an alternation of ridges and troughs.

The next embodiments may apply to the manufacturing method as well as to the integrated circuit.

According to an embodiment, the root mean square height of the ridges formed on the first surface of the protection layer with respect to a determined average level of said first surface is greater than or equal to 5 nanometers.

According to an embodiment, the interconnection elements comprise copper conductive vias.

According to an embodiment, the interconnection elements further comprise at least one copper conductive pad.

According to an embodiment, the integrated circuit comprises a metallization layer in a trench formed in the protection layer and extending all the way to a conductive pad, said metallization layer forming an outgrowth on the first surface of said protection layer.

According to an embodiment, the protection layer comprises:
a first nitride layer, for example, made of silicon nitride or of silicon carbonitride, on the first surface of the interconnection structure;
an oxide layer, for example, made of silicon oxide, on the first nitride layer;
a second nitride layer, for example, made of silicon nitride or of silicon carbonitride, on the oxide layer.

According to a specific embodiment, the alternation of ridges and troughs is formed in the second nitride layer.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 shows an interconnection structure of an integrated circuit;

FIG. 2 is an image of an integrated circuit, such as that of FIG. 1, encapsulated in a resin;

FIG. 3A, FIG. 3B, FIG. 3C, and FIG. 3D are cross-section views illustrating an interconnection structure at the end of the successive steps of an example of a manufacturing method according to an embodiment;

FIG. 4A, FIG. 4B, FIG. 4C, and FIG. 4D are cross-section views illustrating an interconnection structure at the end of the successive steps of another example of a manufacturing method according to an embodiment;

FIG. 5A, FIG. 5B, FIG. 5C, and FIG. 5D are cross-section views illustrating an interconnection structure at the end of the successive steps of another example of a manufacturing method according to an embodiment;

FIG. 6A, FIG. 6B, FIG. 6C, and FIG. 6D are cross-section views illustrating an interconnection structure at the end of the successive steps of another example of a manufacturing method according to an embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, the steps and elements that are useful for an understanding of the embodiments described herein have been illustrated and described in detail. In particular, the drawings show the upper level of the interconnection structure, that is, the level most distant from the semiconductor layer (substrate) having said interconnection structure resting thereon. Further, the drawings show in said upper level vias and conductive pads extending in an insulating layer of said upper level, although the latter may comprise one or a plurality of conductive tracks and/or other insulating layers. The interconnection structure further generally comprises other levels under the upper level where other interconnection elements are arranged.

The vias and the conductive pads may be generally designated as “interconnection elements”, where the interconnection elements may also comprise conductive tracks.

By convention, it is considered in the following description that the protection layer forms part of the interconnection structure. The upper surface of the interconnection structure before the deposition of the protection layer may be designated as the “upper surface” of the interconnection structure. The upper surface of the interconnection structure coated with the protection layer may be designated as the “passivated upper surface” of the interconnection structure. The interconnection structure coated with the protection layer may be designated as the “passivated interconnection structure”.

For clarity also, the substrate having electronic components formed inside and/or on top of it is not shown in the drawings.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

When reference is made to an upper layer, level, side, or surface, reference is made to the layer, level, side or surface most distant from the substrate, as compared with another layer, level, side or surface closer to the substrate.

All along the present description, a height as well as a thickness designate a dimension along a vertical direction (Z direction identified in the drawings), a width designates a dimension along the X direction identified in the drawings. The Y direction is not shown in the drawings but it corresponds to the direction perpendicular to the X and Z directions. The X and Y directions form an XY plane designated as being the main plane of an integrated circuit.

Unless specified otherwise, the expressions “around”, “approximately”, “substantially” and “in the order of” signify within 10%, and preferably within 5%.

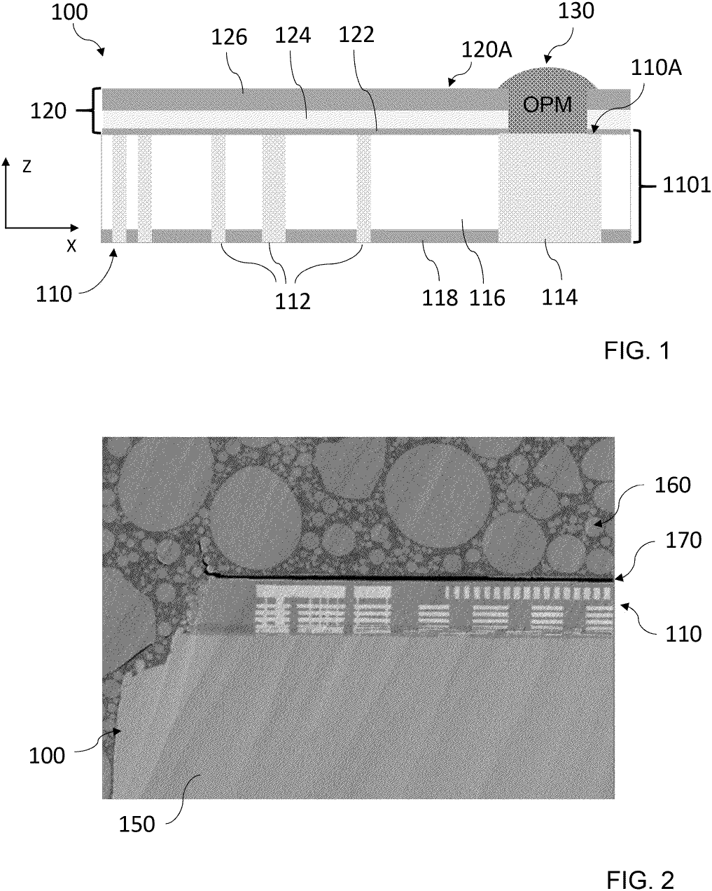

FIG. 1 shows an upper level 1101 of an interconnection structure 110 of an integrated circuit 100, said upper level comprising conductive vias 112 and a conductive pad 114, said vias and pad crossing an insulating layer 116 and a first nitride layer 118. The first nitride layer 118 is arranged under insulating layer 116. The vias and the pad are flush with the upper surface 110A of interconnection structure 110 (corresponding to the upper surface of the upper level 1101 of said interconnection structure) and extend depthwise in insulating layer 116 at least all the way to the lower surface of first nitride layer 118.

Interconnection structure 110 is coated with a protection layer 120, which comprises:
a second nitride layer 122 arranged on the upper surface 110A of interconnection structure 110;
an oxide layer 124 arranged on second nitride layer 122;
a third nitride layer 126 arranged on oxide layer 124.

Above conductive pad 114, protection layer 120 has been etched across its entire thickness, that is, all the way to said pad, to form a trench. Then, a metallization layer 130 has been formed in the trench to be in contact with said pad. This over-pad metallization, called “OPM”, forms an outgrowth which protrudes from the passivated upper surface 120A of interconnection structure 110.

Vias 112 and pad 114 are made of copper (Cu). As explained hereafter, they are formed by a damascene method, comprising a step of polishing of the upper surface of the integrated circuit, so that the vias and the copped pad are flush with the passivated upper surface 120A of the interconnection structure. Indeed, due to this polishing step, the upper surface 110A of the interconnection structure is planar. Thereby, the protection layer 120 which is deposited on said planar upper surface also has a planar upper surface 120A.

The inventors have observed that such a planar surface made the encapsulation of such an integrated circuit in resin more difficult when said circuit is assembled in an electronic package: a phenomenon of delamination of the encapsulation resin can be observed at the interface between said resin and the interconnection structure. This is visible in the image of FIG. 2 which shows an integrated circuit 100, such as that of FIG. 1, comprising an interconnection structure 110 on a substrate 150, the integrated circuit being encapsulated in a resin 160, and the delamination 170 between interconnection structure 110 and resin 160 can be observed.

A solution to this delamination phenomenon is to form an interface layer adapted to adhering both to the integrated circuit and to the encapsulation resin, for example, a polyimide layer. However, such a solution includes an anneal of the polyimide layer to crosslink the polyimide material, which includes heating the integrated circuit/interface layer/resin assembly, and which may be problematic, or even incompatible, when the substrate of the integrated circuit comprises certain components, such as for example a phase change memory (PCM).

The inventors provide an improved interconnection structure enabling to overcome all or part of the previously-mentioned disadvantages of interconnection structures, particularly enabling to do away with an anneal step.

Examples of interconnection structures and of methods of manufacturing such interconnection structures will be described hereafter. These examples are non-limiting and various alterations will occur to those skilled in the art based on the indications of the present disclosure.

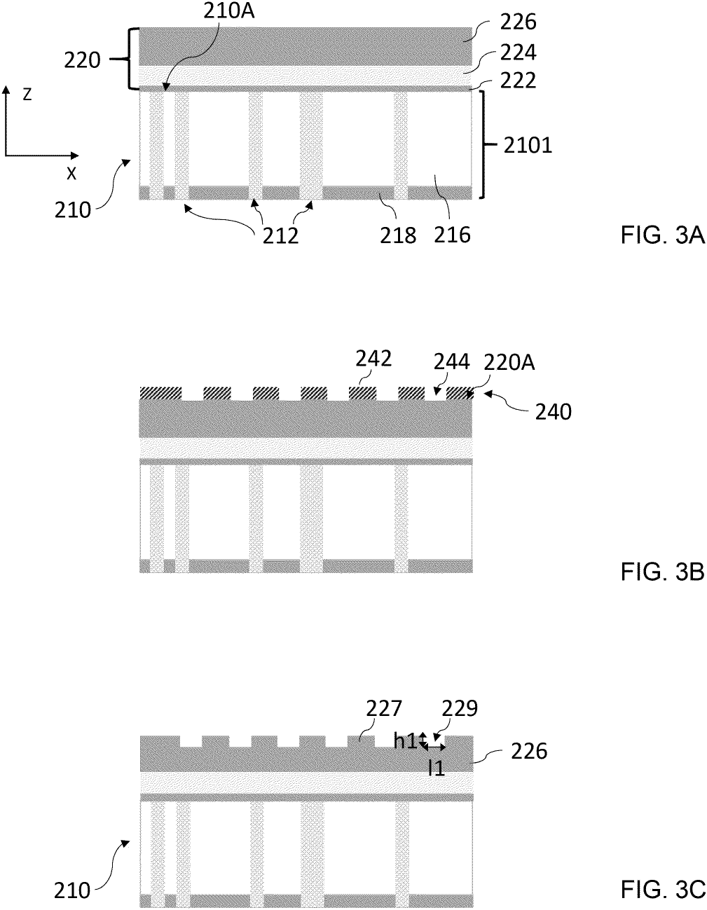

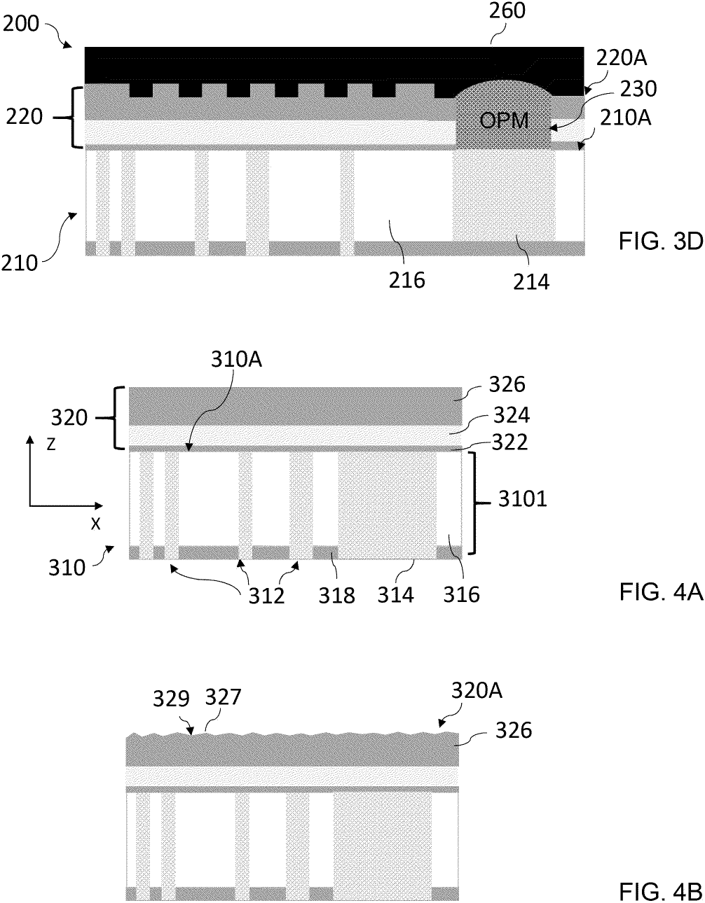

FIGS. 3A to 3D illustrate an example of an interconnection structure manufacturing method according to an embodiment, as well as the obtained interconnection structure.

FIG. 3A illustrates an initial structure. The initial structure comprises an upper level 2101 of an integrated circuit interconnection structure 210. Said upper level comprises vias 212 and a pad 214 (shown in FIG. 3D), the vias and the pad being conductive and crossing an insulating layer 216 and a first nitride layer 218. First nitride layer 218 is under insulating layer 216 and may form a diffusion barrier layer and an etch stop layer.

Insulating layer 216 is for example made of silicon dioxide (SiO2). First nitride layer 218 is for example made of silicon nitride (SiN) or of silicon carbonitride (SiCN).

Vias 212 and pad 214 are flush with the upper surface 210A of interconnection structure 210 (corresponding to the upper surface of the upper level 2101 of said interconnection structure) and extend depthwise into insulating layer 216, for example, at least down to the lower surface of first nitride layer 218, as shown. All or part of the vias and/or of the pad may be in contact with other vias in interconnection structure 210 in a lower level (not shown). The vias and the pad are made of copper (Cu).

Interconnection structure 210 is coated with a protection layer 220, shown as a multilayer structure, comprising:
a second nitride layer 222, for example, silicon nitride (SiN), arranged on the upper surface 210A of interconnection structure 210;
an oxide layer 224, for example, made of silicon oxide (Si02) arranged on second nitride layer 222;
a third nitride layer 226, for example, made of silicon nitride (SiN), arranged on oxide layer 224.

The thickness of second nitride layer 222 may be in the range from approximately 10 to 40 nm, for example, equal to approximately 20 nm. The thickness of oxide layer 224 may be in the range from approximately 400 to 600 nm, for example, equal to approximately 500 nm. The thickness of third nitride layer 226 may be in the range from approximately 300 to 700 nm, for example, equal to approximately 500 nm.

Oxide layer 224 for example forms a so-called “getter” layer intended to trap alkaline ions. Nitride layers 222, 226 for example enable to form a physical barrier to the diffusion of alkaline ions. Protection layer 220 is adapted to protecting the integrated circuit, and in particular the interconnection structure.

The different layers of the protection layer may be formed by a chemical vapor deposition (CVD) technique, particularly by a plasma-enhanced chemical vapor deposition (PECVD) technique.

FIG. 3B illustrates the structure obtained at the end of a step of photolithography performed on the upper surface 220A of protection layer 220, in which step a resin pattern 240 is formed on said protection layer. In cross-section view, the illustrated pattern 240 may be in the form of a succession of rectangular protrusions 242 separated by openings 244, as shown.

The pattern may be obtained by conventional photolithography steps, that is:
the deposition of at least one resin layer including at least one resist layer;
the exposure of the resist layer to a radiation through a mask formed of opaque and transparent areas defined to obtain in said resist a desired pattern; and
the dissolving in a specific aqueous or organic solution, called developer solution, of a portion of the resist layer to develop the pattern.

The shown pattern is for example obtained by using a positive resist. The resist portion exposed to the radiation (through the transparent areas of the mask) becomes soluble in the development solution, and the resist portion which is not exposed (through the opaque areas of the mask) remains non-soluble in the development solution. As a variant, the resist may be negative. The resist portion exposed to the radiation then becomes non-soluble in the developer solution and the non-exposed resist portion remains soluble in the developer solution.

The at least one resin layer may be a monolayer or have a multilayer structure comprising a stack of resin layers, at least one of which is photosensitive. According to an example of embodiment, the resist layer is a multilayer structure comprising a carbon resin layer, an anti-reflection resin layer, and a resist layer. Openings 244 are then defined through these three resin layers.

FIG. 3C illustrates the interconnection structure 210 obtained at the end of a subsequent step of etching from the upper surface 220A of protection layer 220 down to a depth h1. In the shown example, the upper layer of the protection layer is etched, that is, third nitride layer 226, and it is preferably partially etched, that is, down to a depth smaller than the thickness of said third nitride layer. The etching is performed via resin pattern 240 forming an etch mask, so that the etching essentially occurs in the openings 244 of said pattern and in the areas which are not covered with said pattern. The etching forms trenches 229 in upper layer 226.

The etching of third nitride layer 226 may be a dry etching, for example implementing a fluorine plasma.

Then, a step of removal of the resin pattern is carried out, for example, by dry etching, for example implementing an oxygen plasma.

At the end of the step of etching of third nitride layer 226 and of the step of removal of pattern 240, the upper surface 220A of protection layer 220 has a crenellated topology structured 227 (that may be designated with the more generic term “ridges”) separated by trenches 229 (that may be designated with the more generic term “troughs”).

According to examples, each trench 229 may have a width 11 in the range from approximately 50 nm to 5 µm, preferably in the range from approximately 50 to 200 nm, for example, equal to approximately 100 nm and/or a height h1 in the range from approximately 50 to 500 nm, preferably in the range from approximately 100 to 200 nm, for example, equal to approximately 150 nm. The width of each trench is defined by the width of openings 244 in resin pattern 240. The height of the trenches is defined by the etching depth.

This trench structuring of the passivated upper surface of the interconnection structure enables to bond an encapsulation resin 260, such as shown in FIG. 3D, during the assembly of the integrated circuit in a package, decreasing, or even canceling, the above-described delamination effect. Further, the disclosed manufacturing method enables to do away with an anneal step, thus enabling to limit the thermal budget undergone by the electronic components present in the substrate, particularly of the temperature-sensitive components.

FIG. 3D is a wider view of the interconnection structure 210 of integrated circuit 200 where copper pad 214 has been shown. All around copper pad 214, in an area unmasked by resin pattern 240, third nitride layer 226 has been etched during the previously-described etch step, down to the same depth. Thus, all around pad 214, the upper surface of protection layer 220 is substantially planar. A resin layer 260 bonded to the upper surface 220A of the protection layer has been shown.

Further, above copper pad 214, protection layer 220 has been etched across its entire thickness, that is, all the way to said pad 214, to form a complementary trench. This complementary etching may be a dry etching, for example implementing a fluorine plasma. Then, a metallization layer has been formed in the complementary trench, generally by electroless growth. This over-pad metallization 230 (OPM) is in contact with copper pad 214 and forms an outgrowth which protrudes from the passivated upper surface 220A of the interconnection structure. Metallization layer 230 is thus adapted to electrically coupling integrated circuit 200 to another integrated circuit. Over-pad metallization 230 for example comprises nickel, palladium, and/or gold or any other adapted metal or metal alloy.

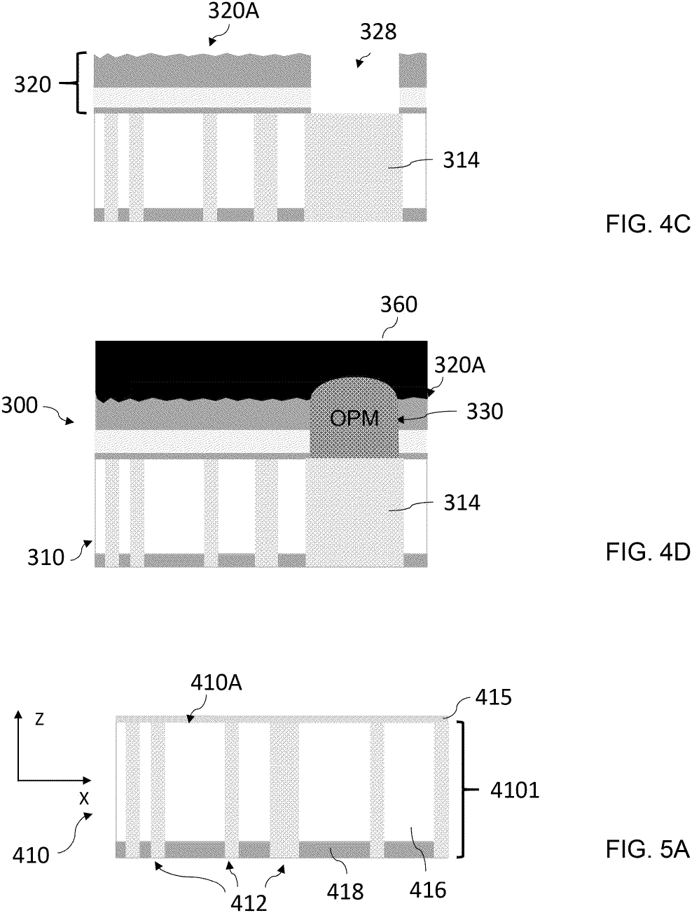

FIGS. 4A to 4D illustrate another example of an interconnection structure manufacturing method according to an embodiment, as well as the obtained interconnection structure.

This other method example can be distinguished from the previous method example mainly in that it does not comprise the photolithography and etch steps described in relation with FIGS. 3B and 3C, the latter being replaced with a polishing step, the obtained interconnection structure mainly differing in that the upper surface of the protection layer exhibits a roughness and not a topology with crenellations separated by trenches.

FIG. 4A illustrates an initial structure, similar to the structure illustrated in FIG. 3A. Thus, the initial structure comprises an upper level 3101 of an interconnection structure 310 of an integrated circuit. The shown upper level 3101 comprises copper vias 312 and a copper pad 314, said vias and said pad crossing an insulating layer 316 and a first nitride layer 318 arranged under insulating layer 316. Interconnection structure 310 is coated with a protection layer 320 shown as a multilayer structure comprising:
a second nitride layer 322 arranged on the upper surface 310A of interconnection structure 310;
an oxide layer 324 arranged on second nitride layer 322;
a third nitride layer 326 arranged on oxide layer 324.

Preferably, third nitride layer 326 has an initial thickness greater than a thickness desired at the end of the polishing step. For example, the initial thickness of third nitride layer 316 is defined so that, at the end of the polishing step, it is substantially equal to approximately 500 nm root mean square at the level of the troughs (defined hereafter). For example, the initial thickness of third nitride layer 326 may be equal to approximately 600 nm.

FIG. 4B illustrates the structure obtained at the end of a step of chemical-mechanical polishing of third nitride layer 326. This polishing is adapted to forming a roughness on the upper surface of said third nitride layer. The roughness is preferably greater than approximately 5 nanometers.

According to an example, the roughness is defined, for a given surface, by the root mean square height of high points (ridges) of the surface with respect to an average level defined for said surface, this definition being known under acronym RMS. The average level for the surface is determined by an average of the heights of the ridges and of the hollows (troughs) on the surface. The values of the ridges and of the hollows (troughs) are measured, for example, by atomic force microscopy, known under acronym AFM.

Such a roughness value may be obtained by using a slurry polishing solution comprising abrasive balls. In an example, the diameters of the abrasive balls are selected to obtain a roughness value indicated hereabove.

Thus, at the end of the polishing step, the upper surface 320A of protection layer 320 has a rough surface provided with ridges 327 and hollows 329 (troughs).

The next steps, illustrated in FIGS. 4C and 4D, are similar to what has been described in relation with FIG. 3D. Thus, above copper pad 314, protection layer 320 has been etched across its entire thickness, that is, all the way to said pad, to form a trench 328, as illustrated in FIG. 4C. This etching may be a dry etching, for example, implementing a fluorine plasma. Then, a metallization layer 330 has been formed in trench 328, generally by growth. As illustrated in FIG. 4D, over-pad metallization 330 (OPM) is in contact with copper pad 314 and forms an outgrowth which protrudes from the passivated upper surface 320A of interconnection structure 310. Over-pad metallization 330 for example comprises nickel, palladium, and/or gold or any other adapted metal or metal alloy.

The forming of this minimum roughness of the passivated upper surface of the interconnection structure enables to bond an encapsulation resin 360, such as shown in FIG. 4D, decreasing, or even canceling, the above-described delamination effect, while doing away with an anneal step. This other manufacturing method example further has the advantage of simplicity, particularly of doing away with a photolithography step and with an etch step, but also of doing away with a step of chemical removal of a resin.

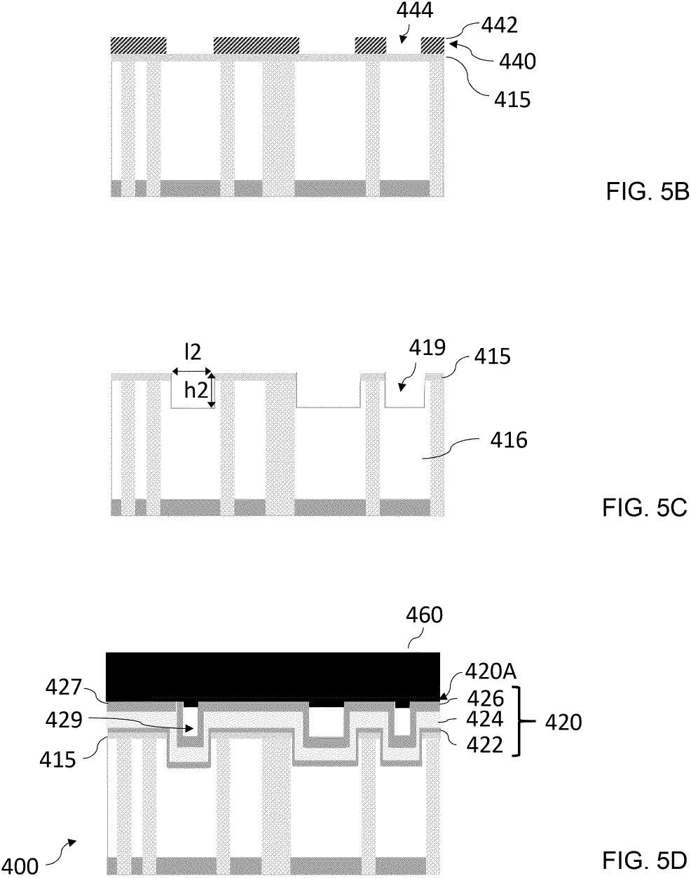

FIGS. 5A to 5D illustrate another example of a method of manufacturing an interconnection structure according to an embodiment, as well as the obtained interconnection structure.

FIG. 5A shows an initial structure, which, as for the initial structures described in relation with FIGS. 3A and 4A, comprises an upper level 4101 of an interconnection structure 410, said upper level comprising conductive vias 412 crossing an insulating layer 416 and a first nitride layer 418. Conductive vias 412 are flush with the upper surface 410A of interconnection structure 401 and extend depthwise in insulating layer 416, for example, at least down to the lower surface of first nitride layer 418, as shown.

However, the initial structure differs from those described in relation with FIGS. 3A and 4A in that the upper surface 410A of interconnection structure 410 is coated with a single layer, which is a single nitride layer 415, for example, made of silicon nitride (SiN) or of silicon carbonitride (SiCN). In other words, the protection layer has not been formed yet. Second nitride layer 415 enables to form an intermediate layer between the copper of the conductive vias and the resin which is intended to be deposited at the next photolithography step. Said intermediate layer forms a diffusion barrier and etch stop layer, as well as a layer for protecting the copper from the environment (for example, from air to avoid oxidation). Further, it is preferable not to perform a photolithography directly on the copper to avoid the oxidation and/or the corrosion of the copper, particularly if the resin has to be removed by a wet cleaning.

FIG. 5B illustrates the structure obtained at the end of a photolithography step carried out on second nitride layer 415, in which step a resin pattern 440 is formed on said second nitride layer. In cross-section view, the illustrated pattern 440 is in the form of a succession of rectangular protrusions 442 arranged vertically in line with vias 412, and separated by openings 444. The photolithography step may be similar to that described in relation with FIG. 3B.

FIG. 5C illustrates the structure obtained at the end of a subsequent step of etching of second nitride layer 415 and of insulating layer 416 down to a depth h2. The insulating layer is preferably partially etched, that is, down to a depth smaller than the thickness of said insulating layer. The etching is performed via resin pattern 440 forming an etch mask, so that the etching essentially occurs in the openings 444 of said pattern and in the areas which are not covered with said pattern. The etching forms trenches 419 in insulating layer 416.

The height h2 of trenches 419 is defined by the etching depth. The height h2 of trenches 419 may be in the range from approximately 20 nm to 300 nm, preferably from approximately 150 to 250 nm, for example equal to approximately 200 nm.

The widths 12 of trenches 419 are preferably greater than or equal to approximately 2 µm to be able to insert the protection layer as described hereafter.

The etching of insulating layer 416 is preferably selective, so as not to etch the copper. This etching of the insulating layer may be a dry etching, for example implementing a fluorine plasma. According to an example, the etching time may be adjusted to etch down to a given depth.

Then, a step of removal of the resin pattern is carried out, similarly to what is described in relation with FIG. 3C.

FIG. 5D illustrates the passivated interconnection structure 410 obtained at the end of a step of forming of a protection layer 420 shown as being a multilayer structure comprising:
a third nitride layer 422 arranged in trenches 419 and on the non-etched portions of second nitride layer 415;
an oxide layer 424 arranged on third nitride layer 422;
a fourth nitride layer 426 arranged on oxide layer 424.

Similarly to what has been described in relation with FIG. 3A, the different layers of the protection layer may be formed by CVD, particularly by PECVD.

At the end of the step of forming of the protection layer with a structuring, the upper surface 420A of protection layer 420 has a structured topology with crenellations 427 (ridges) separated by trenches 429 (troughs). This structuring of the passivated upper surface of the interconnection structure enables to bond encapsulation resin 460, such as shown in FIG. 5D, decreasing, or even canceling, the above-described delamination effect, while doing away with an anneal step.

Although this is not shown, the interconnection structure may comprise a conductive pad and an over-pad metallization layer, similarly to what is described in relation with FIG. 3D.

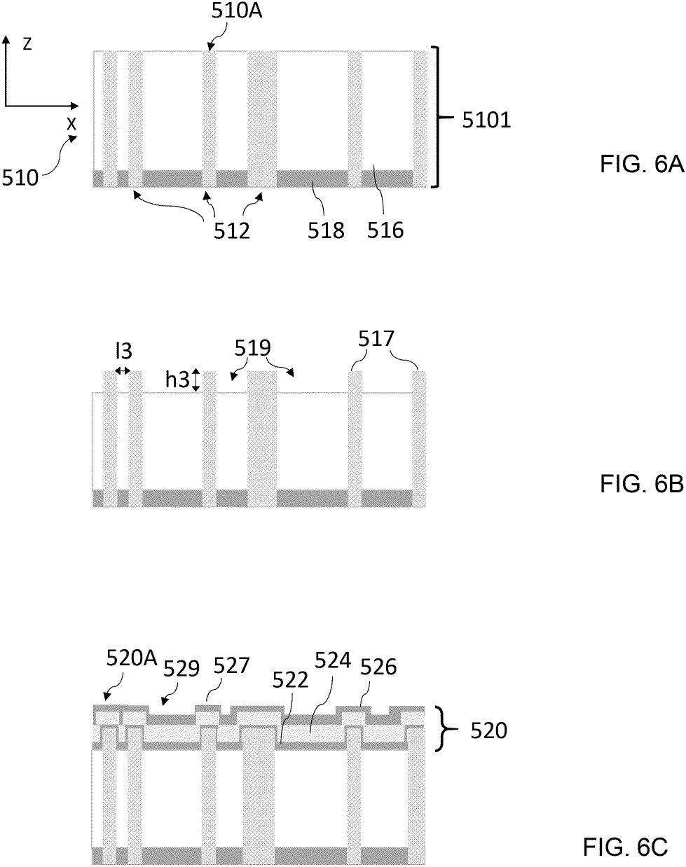

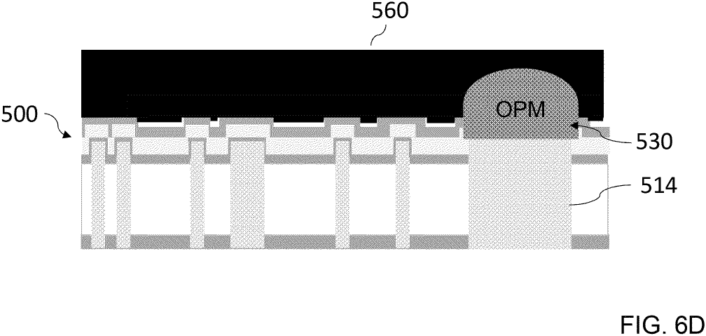

FIGS. 6A to 6D illustrate another example of an interconnection structure manufacturing method according to an embodiment, as well as the obtained interconnection structure. This other method example differs from the method example described in relation with FIGS. 5A to 5D mainly in that it comprises no photolithography step. For example, it is not necessary to deposit a nitride layer on the upper surface of the interconnection structure.

FIG. 6A illustrates an initial structure, which comprises an upper level 5101 of an interconnection structure 510, said upper level comprising conductive vias 512 and a conductive pad 514 (shown in FIG. 6D) crossing an insulating layer 516 and a first nitride layer 518. Conductive vias 512 are flush with the upper surface 510A of interconnection structure 510 and extend depthwise into insulating layer 516, for example, at least down to the lower surface of first nitride layer 518, as shown.

FIG. 6B illustrates the structure obtained at the end of a subsequent step of etching of insulating layer 516 around conductive vias 512 and conductive pad 514 (shown in FIG. 6D) down to a depth h3. The insulating layer is preferably partially etched, that is, down to a depth smaller than the thickness of said insulating layer. The etching enables to hollow the insulating layer all around conductive vias 512 and conductive pad 514, thus forming copper protrusions 517 and trenches 519 between the protrusions.

The height of the trenches is defined by the etching depth. The height h3 of trenches 519 may be in the range from approximately 20 nm to 100 nm, preferably in the range from approximately 25 to 75 nm, for example, equal to approximately 50 nm.

The widths 13 of trenches 519 are defined by the distances between vias 512 or between a via 512 and a pad 514.

The etching of insulating layer 516 is preferably selective, so as not to etch the copper. The etching of the insulating layer may be a dry etching, for example implementing a fluorine plasma, or a wet etching, particularly by means of a fluorinated acid solution, for example, hydrofluoric acid. According to an example, the acid concentration in the solution and/or the etching time may be adjusted to etch down to a given depth.

FIG. 6C illustrates the passivated interconnection structure 510 obtained at the end of a step of forming of a protection layer 520 shown as a multilayer structure comprising:
a second nitride layer 522 arranged on copper protrusions 517 and in trenches 519;
an oxide layer 524 arranged on second nitride layer 522;
a third nitride layer 526 arranged on oxide layer 524.

Similarly to what has been described in relation with FIG. 3A or FIG. 5D, the different layers of the protection layer may be formed by CVD, particularly by PECVD.

At the end of the step of forming of the protection layer with a structuring, the upper surface 520A of protection layer 520 has a structured topology with crenellations 527 (ridges) separated by trenches 529 (troughs). This structuring of the passivated upper surface of the interconnection structure enables to bond encapsulation resin 560, such as shown in FIG. 6D, decreasing, or even canceling, the above-described delamination effect, while doing away with an anneal step. This other example of a manufacturing method further has the advantage of simplicity, particularly of doing away with a photolithography step, but also of doing away with a step of chemical removal of a resin.

FIG. 6D is a wider view of the interconnection structure 510 of integrated circuit 500 where copper pad 514 has been shown. Similarly to what has been described in relation with FIG. 3D or FIGS. 4C and 4D, protection layer 520 has been etched across its entire thickness, that is, all the way to said pad, to form a complementary trench, and then a metallization layer has been formed in the complementary trench. Over-pad metallization 530 (OPM) is in contact with copper pad 514 and forms an outgrowth which protrudes from the passivated upper surface 520A of interconnection structure 510. Over-pad metallization 530 for example comprises nickel, palladium, and/or gold or any other adapted metal or metal alloy. Encapsulation resin 560 is deposited over this assembly.

The manufacturing method according to the different embodiments and the obtained interconnection structure may find applications in field using integrated circuits intended to be encapsulated in an encapsulation resin, with an associated risk of delamination. The manufacturing method and the obtained interconnection structure may particularly find applications for integrated circuits integrating a phase-change memory (PCM).

Various embodiments and variants have been described. Those skilled in the art will understand that certain features of these various embodiments and variants may be combined, and other variants will occur to those skilled in the art. In particular, an interconnection structure may comprise a plurality of conductive pads and a plurality of over-pad metallizations (OPM). The protection layer may be different from that disclosed in the different examples, for example comprise one or two layers, or even more than three layers, and/or each different layer may be made of materials different from those described, while fulfilling similar functions.

For example, the protection layer may comprise a fourth layer above or below the three layers described. This fourth layer is made of an insulating or dielectric material, for example an alloy or a compound comprising aluminum or hafnium, for example: Al₂O₃, HfO2, HfᵢAlⱼOₖ, AlN, AlᵢNⱼOₖ, HfNᵢ (where i, j and k are freely selectable by the person skilled in the art).

Finally, the practical implementation of the described embodiments and variations is within the abilities of those skilled in the art based on the functional indications given hereabove.

Various embodiments disclosed herein provide a method of manufacturing an interconnection structure (210, 310, 410, 510) of an integrated circuit (200, 300, 400, 500) intended to be encapsulated in an encapsulation resin in contact with a first surface (220A, 320A, 420A, 520A) of a protection layer (220, 320, 420, 520), a second side of said protection layer resting on a first surface (210A, 310A, 410A, 510A) of the interconnection structure, the interconnection structure comprising copper interconnection elements (212, 214, 312, 314, 412, 512, 514) extending at least partly through an insulating layer (216, 316, 416, 516) and flush with the first surface of said interconnection structure so that the second side of the protective layer is in contact with said copper interconnecting elements. The manufacturing method may be summarized as including a step of structuring of the protection layer or a step of forming of the protection layer with a structuring, said structuring step or said forming step being adapted to structuring the first surface of the protection layer in the form of an alternation of ridges (227, 327, 427, 527) and troughs (229, 329, 429, 529).

The structuring step may include:
a photolithography step adapted to forming a resin pattern (240) on the first surface (220A) of the protection layer (220), said formed resin pattern being in the form of a succession of protrusions (242) separated by openings (244); and then
a step of etching from the first surface (220A) of the protection layer (220), said etch step being adapted to etching at least a portion of said protection layer and being carried out via the resin pattern (240) forming an etch mask, to form in said protection layer ridges (227) separated by troughs (229).

The widths (11) of the troughs (229) may be in the range from 50 nm to 5 µm, preferably in the range from 50 to 200 nm, and/or the height (h1) of the troughs (229) may be in the range from 50 nm to 500 nm, preferably in the range from 100 to 200 nm.

The structuring step may include a step of chemical-mechanical polishing of the first surface (320A) of the protection layer (320), said polishing step being adapted to forming a roughness greater than or equal to 5 nanometers, on the first surface of said protection layer, the roughness being defined by the root mean square height of the ridges of a surface with respect to an average level defined for said surface.

The polishing step may implement a slurry polishing solution comprising abrasive balls.

The step of forming of the protection layer with a structuring may include: - a step of etching of a first surface of the insulating layer (416, 516) from the first surface (410A, 510A) of the interconnection structure (410, 510), said etching step being carried out between interconnection elements (412, 512, 514), to form trenches (419, 519) between said interconnection elements in said insulating layer, so that at least a portion of said interconnection elements protrudes above the first surface of the etched insulating layer;
a step of forming of a protection layer (420, 520) in the trenches (419, 519) and on the protruding portion of the interconnection elements; said etching and forming steps being adapted to structuring the first surface (420A, 520A) of the protection layer in the form of an alternation of ridges (427, 527) and troughs (429, 529).

The widths (12) of the trenches (419) may be preferably greater than or equal to 2 µm and/or the height (h2) of the trenches (419) may be in the range from 20 to 300 nm, preferably from 150 to 250 nm.

The height (h3) of the trenches (519) may be in the range from 20 to 100 nm, preferably in the range from 25 to 75 nm.

The step of forming of the protection layer with a structuring may include, prior to the step of etching of the insulating layer (416):- a photolithography step adapted to forming a resin pattern (440) on the first surface (410A) of the interconnection structure (410), the formed resin pattern being in the form of a succession of protrusions (442) separated by openings (444); the step of etching of the insulating layer (416) being carried out via the resin pattern (440) forming an etch mask, the protrusions (442) being positioned to mask at least the interconnection elements (412).

The protection layer (420, 520) may be formed by a chemical vapor deposition technique, for example, by plasma-enhanced chemical vapor deposition.

An integrated circuit (200, 300, 400, 500) may be summarized as including an interconnection structure (210, 310, 410, 510) resting on a semiconductor layer, said integrated circuit being intended to be encapsulated in an encapsulation resin in contact with a first surface (220A, 320A, 420A, 520A) of a protection layer (220, 320, 420, 520), a second side said protection layer resting on a first surface (210A, 310A, 410A, 510A) of the interconnection structure, the interconnection structure including interconnection elements (212, 214, 312, 314, 412, 512, 514) at least partly extending through an insulating layer (216, 316, 416, 516) and flush with the first surface of said interconnection structure so that the second side of the protective layer is in contact with said copper interconnecting elements, the first surface of the protection layer being structured in the form of an alternation of ridges (227, 327, 427, 527) and troughs (229, 329, 429, 529).

The mean quadratic height of the ridges (227, 327, 427, 527) formed on the first surface (220A, 320A, 420A, 520A) of the protection layer (220, 320, 420, 520) with respect to a determined average level of said first surface may be greater than or equal to 5 nanometers.

The interconnection elements may include copper conductive vias (212, 312, 412, 512).

The interconnection elements may further include at least one copper conductive pad (214, 314, 514).

The integrated circuit (200, 300, 500) may include a metallization layer (230, 330, 530) in a trench (328) formed in the protection layer (220, 320, 520) and extending all the way to a conductive pad (214, 314, 514), said metallization layer forming an outgrowth of the first surface (220A, 320A, 520A) of said protection layer.

The protection layer (220, 320, 420, 520) may include - a first nitride layer (222, 322, 422, 522), for example, made of silicon nitride or of silicon carbonitride, on the first surface (210A, 310A, 410A, 510A) of the interconnection structure (210, 310, 410, 510);
an oxide layer (224, 324, 424, 524), for example, made of silicon oxide, on the first nitride layer (222, 322, 422, 522);
a second nitride layer (226, 326, 426, 526) for example, made of silicon nitride or of silicon carbonitride, on the oxide layer (224, 324, 424, 524).

The alternation of ridges (227, 327, 427, 527) and troughs (229, 329, 429, 529) may be formed in the second nitride layer (226, 326, 426, 526).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
manufacturing an interconnection structure of an integrated circuit, the interconnection structure including an insulating layer and conductive interconnection elements extending through the insulating layer and flush with a first surface of the interconnection structure; and
forming a protection layer on the first surface of the interconnection structure, the protection layer contacting the conductive interconnection elements, the protection layer including an alternation of ridges and troughs in a first surface of the protection layer, the protection layer contacting the .

2. The method according to claim 1, wherein the forming of the protection layer includes:
forming, by photolithography, a resin pattern on the first surface of the protection layer, the resin pattern being a succession of protrusions separated by openings; and
forming the ridges separated by the troughs in the protection layer by etching from the first surface of the protection layer, the etching including etching at least a portion of the protection layer using the resin pattern as an etch mask.

3. The method according to claim 2, wherein widths of the troughs is in a range from 50 nanometers to 5 micrometers and heights of the troughs is in a range from 50 nanometers to 500 nanometers.

4. The method according to claim 1, wherein the forming of the protection layer includes:
chemical-mechanical polishing the first surface of the protection layer, the polishing including forming a roughness greater than or equal to 5 nanometers, on the first surface of the protection layer, the roughness being defined by a root mean square height of ridges of a surface with respect to an average level defined for the surface.

5. The method according to claim 4, wherein the polishing includes implementing a slurry polishing solution including abrasive balls.

6. The method according to claim 1, wherein the forming of the protection layer includes:
forming trenches between the interconnection elements in the insulating layer such that at least a protruding portion of the interconnection elements protrudes above a first surface of the insulating layer, the forming of the trenches including etching the first surface of the insulating layer from the first surface of the interconnection structure, the etching being carried out between the interconnection elements; and
forming of the protection layer in the trenches and on the protruding portion of the interconnection elements.

7. The method according to claim 6, wherein widths of the trenches are greater than or equal to 2 micrometers and heights of the trenches are in a range from 20 to 300 nanometers.

8. The method according to claim 6, wherein heights of the trenches are in a range from 20 to 100 nanometers.

9. The method according to claim 6, wherein the forming of the protection layer includes, prior to the etching of the first surface of the insulating layer:
forming, by photolithography, a resin pattern on the first surface of the interconnection structure, the resin pattern including a succession of protrusions separated by openings, the etching of the first surface of the insulating layer being carried out via the resin pattern forming an etch mask, the protrusions being positioned to mask at least the interconnection elements.

10. The method according to claim 6, wherein the protection layer is formed by a chemical vapor deposition technique.

11. The method according to claim 1, further comprising:
forming encapsulation resin in contact with the first surface of the protection layer.

12. An integrated circuit comprising:
a semiconductor layer;
an interconnection structure on the semiconductor layer, the interconnection structure including an insulating layer and interconnection elements at least partly extending through the insulating layer and flush with a first surface of the interconnection structure;
a protection layer on the first surface of the interconnection structure, , a first surface of the protection layer being an alternation of ridges and troughs.

13. The integrated circuit according to claim 12, wherein a mean quadratic height of the ridges formed on the first surface of the protection layer with respect to a determined average level of the first surface is greater than or equal to 5 nanometers.

14. The integrated circuit according to claim 12, wherein the interconnection elements includes copper conductive vias.

15. The integrated circuit according to claim 14, wherein the interconnection elements includes at least one copper conductive pad.

16. The integrated circuit according to claim 15, further comprising:
a metallization layer in a trench formed in the protection layer and extending to a conductive pad, the metallization layer forming an outgrowth of the first surface of the protection layer.

17. The integrated circuit according to claim 12, wherein the protection layer includes:
a first nitride layer on the first surface of the interconnection structure;
an oxide layer on the first nitride layer;
a second nitride layer on the oxide layer.

18. The integrated circuit according to claim 17, wherein the alternation of ridges and troughs are formed in the second nitride layer.

19. The integrated circuit according to claim 12, further comprising:
encapsulation resin in contact with the first surface of the protection layer.

20. A method, comprising:
forming an interconnection structure on a substrate, the forming of the interconnection structure including:
forming a first nitride layer;
forming an insulating layer on the first nitride layer; and
forming interconnection elements extending through the insulating layer;
forming a protection layer on the interconnection structure, the forming of the protection layer including:
forming a second nitride layer on the insulating layer;
forming an oxide layer on the second nitride layer; and
forming a third nitride layer on the oxide layer;
forming troughs in the third nitride layer; and
forming encapsulation material on the protection layer and in the troughs in the third nitride layer.

21. The method of claim 20, wherein the forming of the troughs includes forming trenches in the third nitride layer.

22. The method of claim 20, wherein
the forming of the troughs includes forming, by chemical-mechanical polishing, a roughness greater than or equal to 5 nanometers in the third nitride layer, and
the roughness is defined by a root mean square height of ridges of a surface with respect to an average level defined for the surface.

23. The method of claim 20, wherein
the forming of the troughs includes forming trenches in the insulating layer
the second nitride layer is formed on the insulating layer and in the trenches;
the oxide layer is formed on the second nitride layer and in the trenches;
the third nitride layer is formed on the oxide layer and in the trenches; and
the encapsulation material is formed on the third nitride layer and in the trenches.
